(19) United States
(12) Patent Application Publication
(10) Pub. No.: US 2026/0291490 A1
(43) Pub. Date: Sep. 24, 2026

(54) ACTIVE GATE CONTROL DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Yusei KIOKA, Shinjuku Tokyo (JP); Shoji OOTAKA, Yokohama Kanagawa (JP); Yoshiharu NITO, Yokohama Kanagawa (JP); Reiji TAGOMORI, Yokohama Kanagawa (JP); Satoru OSHITA, Hadano Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/367,914

(22) Filed: Oct. 24, 2025

(30) Foreign Application Priority Data
Mar. 24, 2025 (JP) 2025-049036

(51) Int. Cl. H03K 17/16; G01R 19/00; H03K 17/284

(52) U.S. Cl. CPC H03K 17/165; G01R 19/0084; H03K 17/284

(57) ABSTRACT

An active gate control device according to an embodiment includes: a gate terminal drive unit that controls a gate voltage of the gate terminal of the semiconductor switching device by controlling a drive current supplied to the gate terminal of the semiconductor switching device in order to operate the semiconductor switching device; a DESAT circuit unit that monitors a detection voltage based on a voltage between the drain and source of the semiconductor switching device, and outputs a detection signal based on the detection voltage; a drive waveform generation unit that generates a gate drive waveform corresponding to a brake of active gate control based on the detection signal, and outputs an active gate control signal to the gate terminal drive unit; and a control unit that controls the operation of the semiconductor switching device by the gate terminal drive unit using a gate control signal.

### CROSS-REFERENCE TO RELATED APPLICATIONS

This application is based upon and claims the benefit of priority from the prior Japanese Patent Application No. 2025-049036, filed on Mar. 24, 2025 the entire contents of which are incorporated herein by reference.

### FIELD

The present embodiment relates to an active gate control device.

### BACKGROUND

For example, when a semiconductor switching device is turned on or off, parasitic elements may cause ringing, in which the current through the device and voltage across its main terminals oscillate.

One method to suppress this ringing is to insert a resistor between the gate terminal of the semiconductor switching device and the output terminal of the gate driver. However, this method may disadvantageously reduce the switching speed.

Active gate control is known as a method for suppressing ringing and an increase in losses while preventing a reduction in switching speed.

Active gate control is a technique for driving a semiconductor switching device, in which the gate drive strength is reduced at an appropriate timing to prevent excessive driving.

Specifically, active gate control drives the semiconductor switching device such that the rate of increase of the gate voltage during turn-on and the rate of decrease during turn-off are reduced.

In this way, reducing the rate of increase of the gate voltage during turn-on and the rate of decrease during turn-off is referred to as “braking.” Active gate control is therefore a technique that adjusts the gate drive to apply braking at an appropriate timing.

### BRIEF DESCRIPTION OF THE DRAWINGS

FIG. 1 is a diagram showing an example of the configuration of a drive system including an active gate control device according to a first embodiment.

FIG. 2 is a diagram showing an example of the circuit configuration of a DESAT circuit unit shown in FIG. 1.

FIG. 3 is a diagram showing an example of the circuit configuration of a drive waveform generation unit shown in FIG. 1.

FIG. 4 is a diagram showing an example of the circuit configuration focusing on the DESAT circuit unit, drive waveform generation unit, and gate terminal drive unit of the active gate control device shown in FIG. 1.

FIG. 5A is a diagram showing an example of each signal and a brake waveform during a turn-on operation of a semiconductor switching device according to a first embodiment.

FIG. 5B is a diagram showing an example of the waveforms of each signal during a turn-on operation of a semiconductor switching device of an active gate control device according to a first embodiment.

FIG. 6A is a diagram showing an example of each signal and a brake waveform during a turn-off operation of a semiconductor switching device according to a first embodiment when ringing is negligibly small.

FIG. 6B is a diagram showing an example of the waveforms of each signal during a turn-off operation of the semiconductor switching device of the active gate control device according to the first embodiment, corresponding to FIG. 6A.

FIG. 7A is a diagram showing an example of each signal and a brake waveform during a turn-off operation of the semiconductor switching device of the active gate control device according to the first embodiment.

FIG. 7B is a diagram showing an example of the waveforms of each signal during a turn-off operation of the semiconductor switching device of the active gate control device according to the first embodiment, corresponding to FIG. 7A.

FIG. 8 is a diagram showing an example of the configuration of a drive system including an active gate control device according to the second embodiment.

FIG. 9 is a diagram showing an example of a circuit configuration focusing on the gate terminal drive unit shown in FIG. 8.

FIG. 10 is a diagram showing an example of a circuit configuration focusing on the gate voltage monitoring unit shown in FIG. 8.

FIG. 11A is a diagram showing an example of signal waveforms for calibrating the monitoring current source and monitoring capacitor of the gate voltage monitoring unit shown in FIG. 8.

FIG. 11B is a diagram showing an example of a signal waveform for calibrating a monitoring resistor of the gate voltage monitoring unit shown in FIG. 8.

FIG. 12 is a diagram showing an example of a circuit configuration focusing on the gate voltage monitoring unit, the drive waveform generation unit, and the gate terminal drive unit of the active gate control device shown in FIG. 8.

FIG. 13A is a diagram showing an example of each signal and a brake waveform during a turn-off operation of a semiconductor switching device according to the second embodiment.

FIG. 13B is a diagram showing an example of a waveform of each signal during a turn-off operation of a semiconductor switching device of the active gate control device according to the second embodiment.

FIG. 14 is a diagram showing an example of a configuration of a drive system including an active gate control device according to the third embodiment.

FIG. 15 is a diagram showing an example of a circuit configuration focusing on the gate voltage monitoring unit shown in FIG. 14.

FIG. 16 is a diagram showing an example of a circuit configuration focusing on the drive waveform generation unit shown in FIG. 14.

FIG. 17 is a diagram showing an example of a circuit configuration focusing on the gate voltage monitoring unit, drive waveform generation unit, and gate terminal drive unit of the active gate control device shown in FIG. 14.

FIG. 18A is a diagram showing an example of each signal and a brake waveform during a turn-off operation of a semiconductor switching device according to a third embodiment.

FIG. 18B is a diagram showing an example of the waveforms of each signal during a turn-off operation of a semiconductor switching device of an active gate control device according to a third embodiment.

FIG. 19 is a diagram showing an example of the configuration of a drive system including an active gate control device according to a fourth embodiment.

FIG. 20 is a diagram showing an example of a circuit configuration focusing on the DESAT circuit unit, gate voltage monitoring unit, drive waveform generation unit, and gate terminal drive unit of the active gate control device shown in FIG. 19.

FIG. 21 is a diagram showing another example of a circuit configuration focusing on the DESAT circuit unit, gate voltage monitoring unit, drive waveform generation unit, and gate terminal drive unit of the active gate control device shown in FIG. 19.

### DETAILED DESCRIPTION

An object of one embodiment is to provide an active gate control device capable of performing active gate control and appropriately suppressing ringing.

An active gate control device, according to one embodiment, that performs active gate control during turn-on or turn-off of a semiconductor switching device, includes:
a gate terminal drive unit that controls a gate voltage of the gate terminal of the semiconductor switching device by controlling a drive current supplied to the gate terminal of the semiconductor switching device in order to operate the semiconductor switching device;
a DESAT circuit unit that monitors a detection voltage based on a voltage between the drain and source of the semiconductor switching device, and outputs a detection signal based on the detection voltage;
a drive waveform generation unit that generates a gate drive waveform corresponding to a brake of active gate control based on the detection signal output by the DESAT circuit unit, and outputs an active gate control signal to the gate terminal drive unit for executing active gate control based on the gate drive waveform; and
a control unit that controls the operation of the DESAT circuit unit, and controls the operation of the semiconductor switching device by the gate terminal drive unit using a gate control signal.

The active gate control device according to the embodiment will be described in detail below with reference to the attached drawings. It is noted that the present invention is not limited to these embodiments.

### First Embodiment

### Drive System

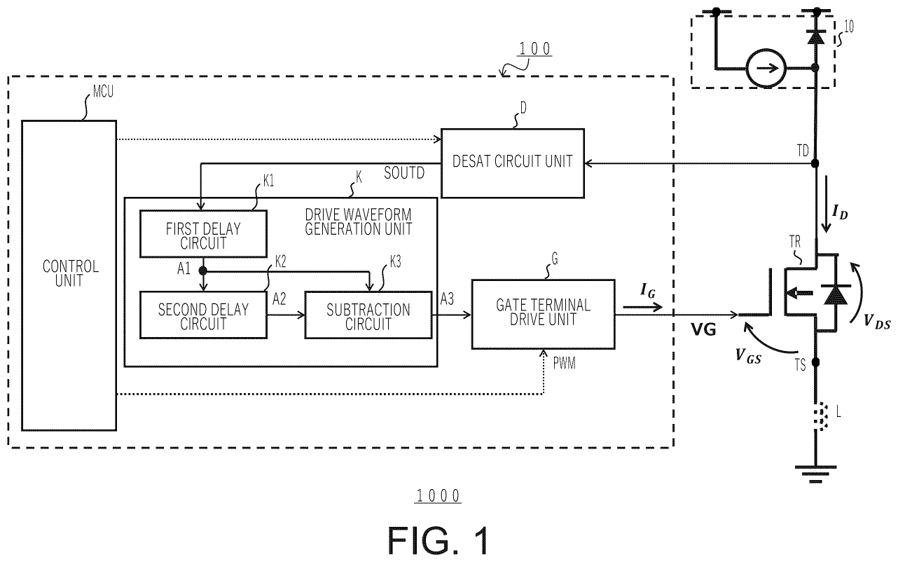

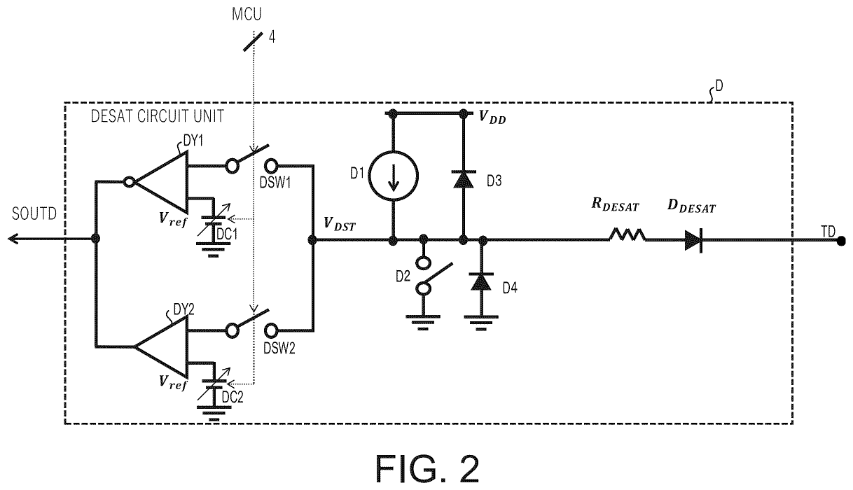

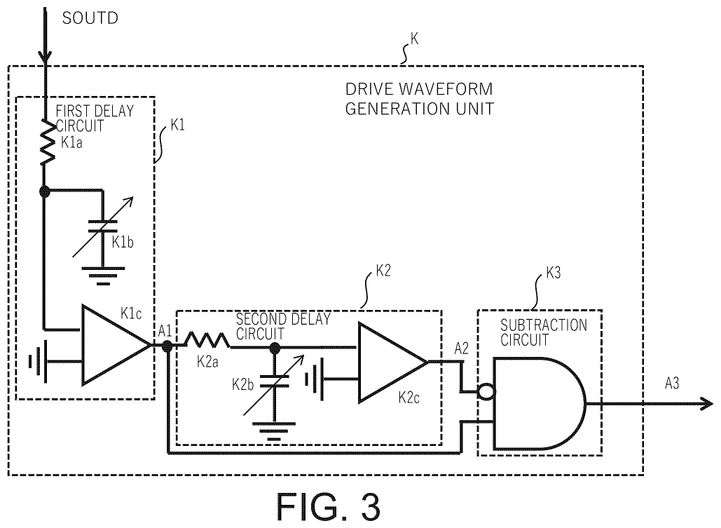

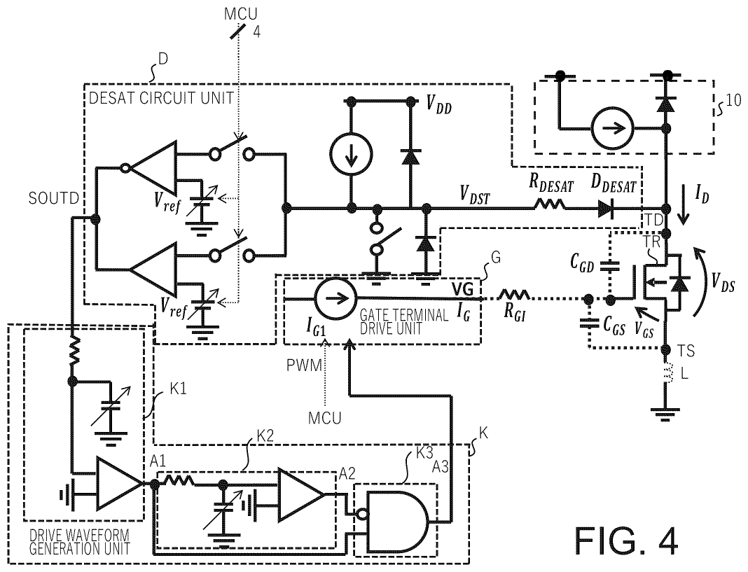

FIG. 1 is a diagram showing an example of the configuration of a drive system including an active gate control device according to a first embodiment. FIG. 2 is a diagram showing an example of the circuit configuration of the DESAT circuit unit shown in FIG. 1. FIG. 3 is a diagram showing an example of the circuit configuration of the drive waveform generation unit shown in FIG. 1. FIG. 4 is a diagram showing an example of the circuit configuration focusing on the DESAT circuit unit, drive waveform generation unit, and gate terminal drive unit of the active gate control device shown in FIG. 1.

It is noted that in the example of FIG. 1, the parasitic capacitance and parasitic resistance around the semiconductor switching device TR are not shown. In addition, in the example of FIG. 4, the dotted lines indicate the parasitic elements of the semiconductor switching device TR.

For example, as shown in FIG. 1, a drive system 1000 includes an active gate control device 100, a semiconductor switching device TR that is the driving target of the active gate control device 100, and a current source 10 that is connected between a power supply and one end (drain terminal) of the semiconductor switching device TR and outputs a current ID.

### Semiconductor Switching Device

The semiconductor switching device TR, which is the driving target of the active gate control device 100, has one end (drain terminal) connected to a current source 10 via a detection terminal TD, the other end (source terminal) connected to a parasitic coil L via a terminal TS, and a gate current IG is supplied to the control terminal (gate terminal), as shown in FIG. 1.

This semiconductor switching device TR is controlled to be in the ON state or in the OFF state by the active gate control device 100, which changes the charge of the parasitic capacitance (not shown) and changes the voltage VG of the gate terminal as a result.

In this embodiment, the semiconductor switching device TR is, for example, an nMOS transistor, as shown in FIG. 1. However, the semiconductor switching device TR may be another semiconductor switching device, such as a pMOS transistor.

### Active Gate Control Device

The active gate control device 100 according to the first embodiment shown in FIG. 1 is configured to perform active gate control during turn-on or turn-off of the semiconductor switching device TR.

In the example shown in FIG. 1, the active gate control device 100 according to the first embodiment has a circuit configuration that detects the timing of braking based on the detection signal SOUTD output from the DESAT circuit unit D.

This active gate control device 100, for example, as shown in FIG. 1, comprises a DESAT circuit unit D, a drive waveform generation unit K, a gate terminal drive unit G, and a control unit MCU.

These configurations of the active gate control device 100 of this embodiment are described in detail below.

### DESAT Circuit Unit

The DESAT circuit unit D monitors the detection voltage VDST based on the drain-source voltage VDS of the semiconductor switching device TR.

Then, when the DESAT circuit unit D detects, based on the detection voltage VDST, that the drain-source voltage VDS is an unsaturated voltage, indicating that an overcurrent is flowing through the semiconductor switching device TR, the DESAT circuit unit D executes a shutdown of the semiconductor switching device TR.

For example, when the semiconductor switching device TR is in the OFF state, the detection voltage VDST is approximately equal to the voltage VDD, which corresponds to a high level.

On the other hand, when the semiconductor switching device TR is turned on and the drain-source voltage VDS decreases, a current flows through the semiconductor switching device TR via the detection resistor RDESAT and the detection diode DDESAT, and the detection voltage VDST decreases to a low level.

The DESAT circuit unit D is configured to output a detection signal SOUTD based on the detection voltage VDST.

Here, the DESAT circuit unit D includes, for example, a detection diode DDESAT, a detection resistor RDESAT, a first detection comparator DY1, a first detection switch DSW1, a first detection variable capacitor DC1, a second detection comparator DY2, a second detection switch DSW2, and a second detection variable capacitor DC2, as shown in FIG. 2.

Furthermore, as a configuration for obtaining the detection voltage VDST, the DESAT circuit unit D may be configured to include, for example, a current source D1, a switch D2, and two diodes D3 and D4, as shown in FIG. 2.

Here, the cathode of the detection diode DDESAT is connected to the detection terminal TD between the power supply circuit 10 and one end (drain terminal) of the semiconductor switching device TR.

One end of the detection resistor RDESAT is connected to the anode of the detection diode DDESAT, and the detection voltage VDST is output to the other end of the detection resistor RDESAT.

The first comparator DY1 receives the detection voltage VDST via the first detection switch DSW1, and also receives the reference voltage Vref stored in the first detection variable capacitor DC1.

The first comparator DY1 outputs a high-level signal when the detection voltage VDST becomes lower than the reference voltage Vref, and outputs a low-level signal when the detection voltage VDST becomes higher than the reference voltage Vref.

The second comparator DY2 receives the detection voltage VDST via the second detection switch DSW2, and also receives the reference voltage Vref stored in the second detection variable capacitor DC2.

The second comparator DY2 outputs a low-level signal when the detection voltage VDST becomes lower than the reference voltage Vref, and outputs a high-level signal when the detection voltage VDST becomes higher than the reference voltage Vref.

In this way, the first comparator DY1 outputs a signal with logic inverted relative to the second comparator DY2.

In addition, when the semiconductor switching device TR is turned on, the control unit MCU turns on the first detection switch DSW1 and turns off the second detection switch DSW2.

As a result, when the semiconductor switching device TR is turned on, the output of the first comparator DY1 is output as the detection signal SOUTD output by the DESAT circuit unit D.

On the other hand, when the semiconductor switching device TR is turned off, the control unit MCU turns off the first detection switch DSW1 and turns on the second detection switch DSW2.

As a result, when the semiconductor switching device TR is turned off, the output of the second comparator DY2 is output as the detection signal SOUTD output by the DESAT circuit unit D.

It is noted that the circuit configuration of the DESAT circuit unit D shown in FIG. 2 is just one example, and the DESAT circuit unit D may alternatively be implemented using any other circuit configuration that can perform a similar function.

### Drive Waveform Generation Unit

The drive waveform generation unit K generates a gate drive waveform corresponding to the active gate control braking based on the detection signal SOUTD output by the DESAT circuit unit D, and outputs an active gate control signal A3 to the gate terminal drive unit G to execute the braking based on the gate drive waveform.

For example, the drive waveform generation unit K detects the starting point for determining the braking start timing of the active gate control based on the change in the detection signal SOUTD output by the DESAT circuit unit D in response to the rising or falling edge of the drain-source voltage VDS of the semiconductor switching device TR.

Then, the drive waveform generation unit K determines the time when the first delay time DX1 has elapsed from the starting point as the braking start timing, and determines the period from the braking start timing to the second delay time DX2 as the brake width for active gate control, thereby generating a gate drive waveform.

Then, the drive waveform generation unit K outputs an active gate control signal A3 to the gate terminal drive unit G, in accordance with the generated gate drive waveform, to execute active gate control.

This drive waveform generation unit K includes, for example, a first delay circuit K1, a second delay circuit K2, and a subtraction circuit K3, as shown in FIG. 3.

The first delay circuit K1, for example as shown in FIG. 3, receives the detection signal SOUTD output by the DESAT circuit unit D and outputs a first signal A1 obtained by delaying the detection signal SOUTD by a first delay time DX1.

More specifically, the first delay circuit K1 includes, for example, as shown in FIG. 3, a resistor K1a to which the detection signal SOUTD is input, a variable capacitor K1b for adjusting the first delay time DX1, and a comparator K1c for outputting the first signal A1.

A first delay time DX1 is added to the detection signal SOUTD input from the DESAT circuit unit D by an RC network including a resistor K1a and a variable capacitor K1b.

Furthermore, the second delay circuit K2 is configured to receive the first signal A1 output by the first delay circuit K1, and output a second signal A2 obtained by delaying the first signal A1 by a second delay time DX2, as shown in FIG. 3, for example.

More specifically, the second delay circuit K2 includes, for example, as shown in FIG. 3, a resistor K2a to which the first signal A1 is input, a variable capacitor K2b for adjusting the second delay time DX2, and a comparator K2c for outputting the second signal A2.

A second delay time DX2 is added to the first signal A1 by an RC network including a resistor K2a and a variable capacitor K2b.

It is noted that the time constant of the RC network of the second delay circuit K2 may be equal to or different from the time constant of the RC network of the first delay circuit K1.

Also, for example, as shown in FIG. 3, the subtraction circuit K3 outputs the difference (hereinafter, A1∩A2 will be referred to as the difference.) between the first signal A1 output by the first delay circuit K1 and the second signal A2 output by the second delay circuit K2 as the third signal A3 for generating a gate drive waveform.

More specifically, the subtraction circuit K3 is an AND circuit that receives the first signal A1 and the inverted signal of the second signal A2, and outputs the third signal A3 as the difference between the two signals by taking the logical product.

In this way, the drive waveform generation unit K outputs the active gate control signal A3 to the gate terminal drive unit G based on the third signal A3.

It is noted that the circuit configuration of the drive waveform generation unit K shown in FIG. 3 is just one example, and the unit may alternatively be implemented using any other configuration capable of performing the same function as the drive waveform generation unit K.

### Gate Terminal Drive Unit

The gate terminal drive unit G controls the gate voltage VG of the gate terminal of the semiconductor switching device TR by controlling the drive current IG supplied to its gate terminal, based on the gate control signal PWM output by the control unit MCU and the active gate control signal A3 output by the drive waveform generation unit K in order to operate the semiconductor switching device TR.

The gate terminal drive unit G controls the operation of the semiconductor switching device TR in response to, for example, the gate control signal PWM, and the gate terminal drive unit G performs active gate control in response to the active gate control signal A3 to control the voltage of the gate terminal of the semiconductor switching device TR so as to brake the turn-on or turn-off operation of the semiconductor switching device TR.

This makes it possible to realize active gate control that reduces the gate drive strength applied to the gate terminal of the semiconductor switching device TR to an appropriate level at the appropriate timing.

This gate terminal drive unit G includes a current source IG1 that outputs a drive current IG in response to the gate control signal PWM output by the control unit MCU and the active gate control signal A3 output by the drive waveform generation unit K, as shown in FIG. 4, for example.

It is noted that the circuit configuration of the gate terminal drive unit G shown in FIG. 4 is just one example, and the gate terminal drive unit G may alternatively be implemented using any other configuration capable of performing the same function as the gate terminal drive unit G.

### Control Unit

The control unit MCU controls the operation of the DESAT circuit unit D, and also controls the operation of the semiconductor switching device TR by the gate terminal drive unit G using a gate control signal PWM (Pulse Width Modulation signal).

### Operation of the Active Gate Control Device

Next, an example of the operation of the active gate control device 100 having the above configuration will be described.

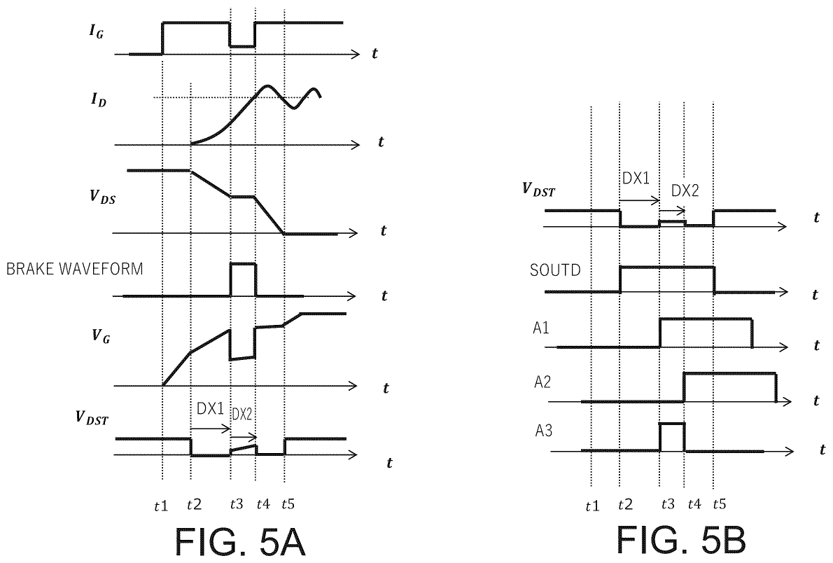

FIG. 5A illustrates an example of each signal and brake waveform when the semiconductor switching device according to the first embodiment is turned on. FIG. 5B illustrates an example of each signal waveform when the semiconductor switching device of the active gate control device according to the first embodiment is turned on. It is noted that in FIG. 5A, the drive current IG is written with the polarity in which the gate voltage VG of the semiconductor switching device TR increases as positive.

For example, as shown in FIGS. 5A and 5B, when a drive current IG flows so that the semiconductor switching device TR turns on at time t1, the drain-source voltage VDS begins to decrease with an increase in the current ID flowing between the drain and source due to the influence of the parasitic inductance of the drain and source terminals of the semiconductor switching device TR (after time t2).

The point at which the drain-source voltage VDS starts to drop (time t2) is set as the starting point, and active gate control braking begins after the first delay time DX1. When the drain-source voltage VDS decreases, current flows through the parasitic capacitance of the detection diode DDESAT and the detection resistor RDESAT shown in FIG. 2, so the detection voltage VDST of the DESAT circuit unit D falls to a low level.

Then, the detection signal SOUTD of the DESAT circuit unit D becomes a high level (time t2) because it is designed to be an inverted output of the detection voltage VDST when turned on.

Then, the drive waveform generation unit K outputs the first signal A1 (after time t3) by delaying the rising edge of this detection signal SOUTD by the first delay time DX1 in the first delay circuit K1 so that the rising edge of the detection signal SOUTD becomes the braking start point of the desired gate drive waveform.

Furthermore, the drive waveform generation unit K delays the first signal A1 by a second delay time DX2 in the second delay circuit K2 so that the rising edge of the detection signal SOUTD becomes the braking end point of the desired gate drive waveform, and outputs the second signal A2 (after time t4).

Then, the drive waveform generation unit K takes the difference between the first signal A1 and the second signal A2, and outputs an active gate control signal A3 whose waveform is equal to the brake waveform.

The drive current IG in FIG. 5A is controlled based on the gate control signal PWM input from the control unit MCU and the active gate control signal A3 (times t3 to t4).

The detection voltage VDST rises slightly during braking the gate drive strength, but this is negligible compared with the changes at the beginning and end of the on-state transient. The polarity of the detection signal SOUTD does not change at the start of braking.

If the change in detection voltage VDST cannot be ignored, the MCU learns the change in detection voltage VDST from t3 to t4, and the reference voltage Vref of comparator DY1 in DESAT circuit unit D is increased to a level where the first detection variable capacitor DC1 does not detect the change in detection voltage VDST from t3 to t4, thereby forcibly setting the detection signal SOUTD to a high level for a certain period of time.

It is noted that since braking timing changes depending on various conditions such as the characteristics of the semiconductor switching device TR, the junction temperature, the applied current, and the voltage, the first delay time DX1 and the second delay time DX2 are set based on separate evaluation data.

In this way, the drive waveform generation unit K detects the starting point (time t2) for determining the braking start timing of the active gate control, based on the transition in the detection signal SOUTD that occurs in response to the falling edge of the drain-source voltage VDS of the semiconductor switching device TR.

Then, the drive waveform generation unit K determines the time (time t3) when the first delay time DX1 has elapsed from the starting point (time t2) as the braking start timing, and determines the period from the braking start timing to the second delay time DX2 as the brake width for active gate control, thereby generating a gate drive waveform.

Then, the drive waveform generation unit K outputs an active gate control signal A3 for executing active gate control to the gate terminal drive unit G based on the gate drive waveform.

Then, as shown in FIGS. 5A and 5B, the gate terminal drive unit G controls the operation of the semiconductor switching device TR in response to the gate control signal PWM (from time t1 onwards). Then, the gate terminal drive unit G controls the voltage of the gate terminal of the semiconductor switching device TR so as to brake the turn-on operation of the semiconductor switching device TR by actively controlling the gate with the drive current IG in response to the active gate control signal A3 (times t3 to t4).

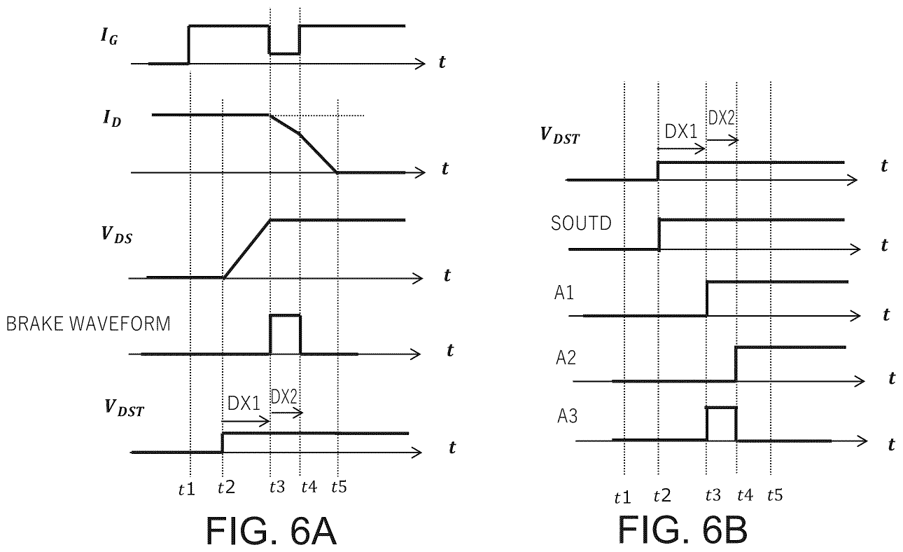

Here, FIG. 6A is a diagram showing an example of each signal and a brake waveform when ringing is small enough to be ignored during the turn-off operation of the semiconductor switching device according to the first embodiment. FIG. 6B is a diagram showing an example of the waveform of each signal during the turn-off operation of the semiconductor switching device of the active gate control device according to the first embodiment, which corresponds to FIG. 6A. Note that in FIG. 6A, the drive current IG is written with the polarity in which the gate voltage VG of the semiconductor switching device TR decreases as positive. Also, FIGS. 6A and 6B show a case where ringing of the drain-source voltage VDS can be ignored.

When the drain-source voltage VDS of the semiconductor switching device TR rises, the potential of the drain terminal of the semiconductor switching device TR increases, current from the current source D1 stops flowing to the semiconductor switching device TR side, the parasitic capacitances of the switch D2, the two diodes D3 and D4, the first detection switch DSW1, and the second detection switch DSW2 are charged, and the detection voltage VDST and the detection signal SOUTD also rise to high level.

The rising edge of this drain-source voltage VDS is the starting point, and after a certain delay, active gate control braking begins.

Similar to the turn-on case, the first delay circuit K1 adds a predetermined delay 1 so that the rising edge of the detection signal SOUTD becomes the braking start point of the desired gate drive waveform, and the signal is output from the A1 terminal. Furthermore, the second delay circuit K2 adds a predetermined delay 2 so that the rising edge of the detection signal SOUTD becomes the braking end point of the desired gate drive waveform, and the signal is output from the A2 terminal.

By taking the difference between the output signals of terminals A1 and A2, a signal waveform corresponding to the brake waveform is output from terminal A3.

It is noted that the braking timing varies depending on various conditions such as the characteristics of the semiconductor switching device TR, the junction temperature, the applied current, and the voltage, so the specified delay 1 and the specified delay 2 must be set based on separate evaluation data.

For example, as shown in FIG. 6A, the gate terminal drive unit G controls the operation of the semiconductor switching device TR in response to the gate control signal PWM (from time t1 onwards). Then, the gate terminal drive unit G performs active gate control in response to the active gate control signal A3 (times t3 to t4) to control the voltage of the gate terminal of the semiconductor switching device TR so as to brake the turn-off operation of the semiconductor switching device TR.

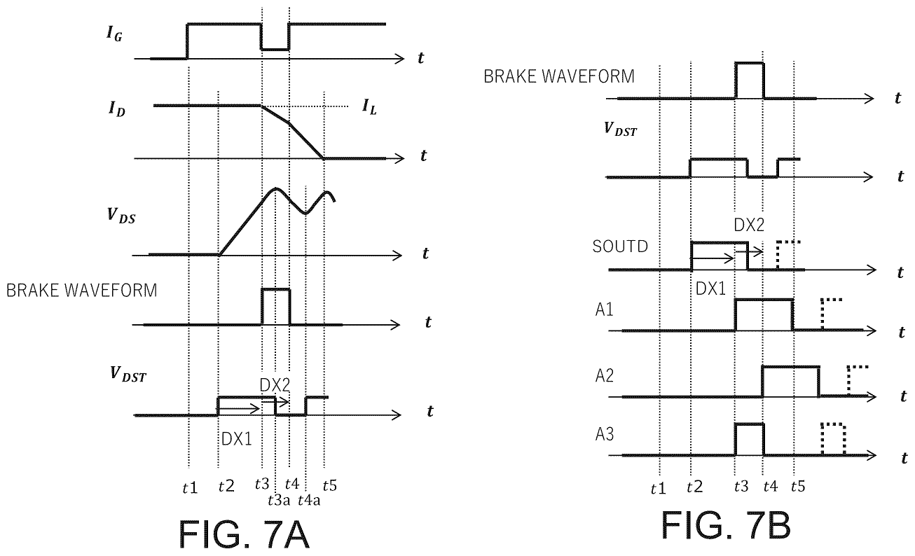

Here, FIG. 7A is a diagram showing an example of each signal and a brake waveform during a turn-off operation of the semiconductor switching device according to the first embodiment. FIG. 7B is a diagram showing an example of the waveform of each signal during a turn-off operation of the semiconductor switching device of the active gate control device according to the first embodiment, corresponding to FIG. 7A. It is noted that in FIG. 7A, the drive current IG is written with the polarity in which the gate voltage of the semiconductor switching device TR decreases as positive. Furthermore, FIGS. 7A and 7B show a case in which the ringing of the drain-source voltage VDS cannot be ignored.

Due to the rising of the drain-source voltage VDS of the semiconductor switching device TR, the voltage VDST and the detection signal SOUTD also rise to a high level.

Even if ringing cannot be ignored, as in the cases of FIGS. 6A and 6B, the rising edge of this drain-source voltage VDS is the starting point, and after the first delay time DX1, active gate control braking begins, and after the second delay time DX2, braking ends.

However, if ringing occurs in the drain-source voltage VDS (time t3a to time t4a), the ringing is also transmitted to VDST via the parasitic capacitance, and if the amplitude of the ringing is greater than the threshold voltage of the second comparator DY2, the output of the second comparator DY2 also changes between a high level and a low level.

As a result, as shown by the dotted line, a drive waveform other than the appropriate brake timing is added to the active gate control signal (third signal) A3, which may result in the brake being inserted multiple times.

In order to avoid this inappropriate braking, when the detection voltage VDST falls due to ringing, the control unit MCU increases the reference voltage Vref of the second comparator DY2 of the DESAT circuit unit D, forcibly setting the detection signal SOUTD to a low level for a certain period of time, thereby setting the detection signal SOUTD to a low level.

It is noted that braking timing changes depending on various conditions such as the characteristics of the semiconductor switching device TR, the junction temperature, the applied current, the voltage, etc. Therefore, the first delay time DX1 and the second delay time DX2 are set based on separate evaluation data.

As described above, the active gate control device 100 according to the first embodiment can execute active gate control and appropriately suppress ringing. In particular, compared to the prior art braking technique (Dibo Zhang, “Digital Gate Driver IC with Fully Integrated Automatic Timing Control Function in Stop-and-Go Gate Drive for IGBTs”, published by 2023 IEEE Applied Power Electronics Conference and Exposition (APEC)), the effect of active gate control can be increased by relatively shortening the brake width and reducing the brake level.

### Second Embodiment

Here, in the first embodiment described above, an example of the configuration of an active gate control device was explained. However, the configuration of this active gate control device is not limited to this. Therefore, in this second embodiment, another example of the configuration of an active gate control device will be explained.

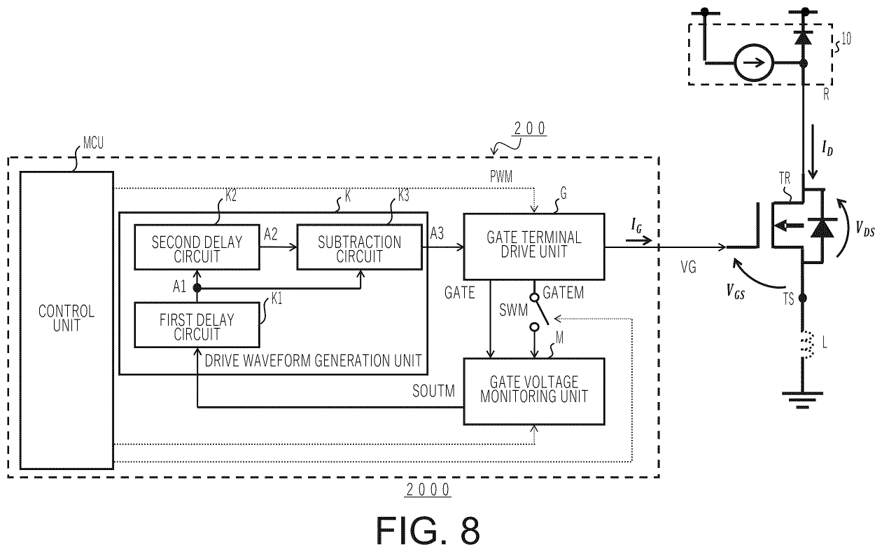

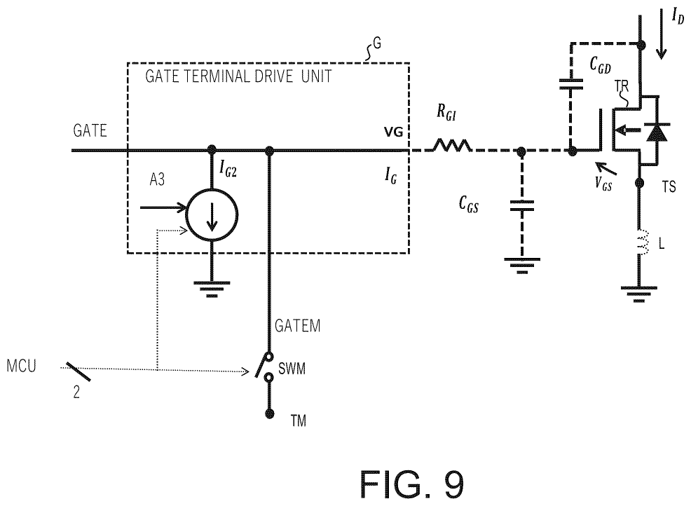

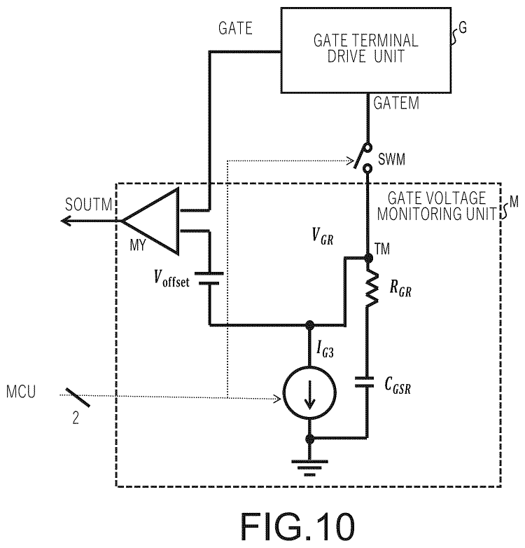

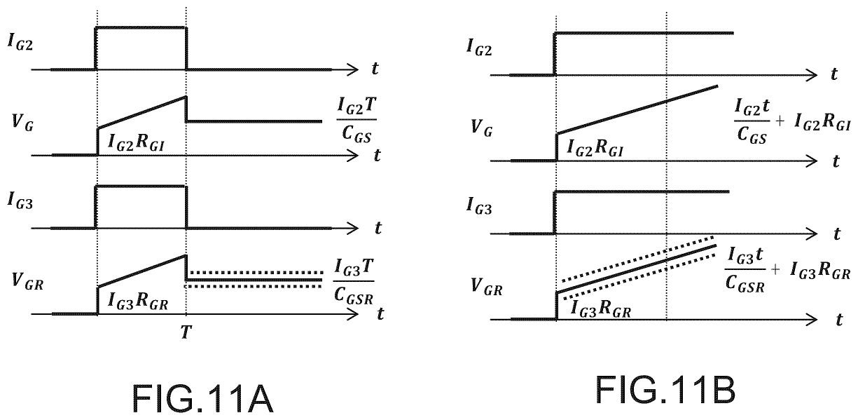

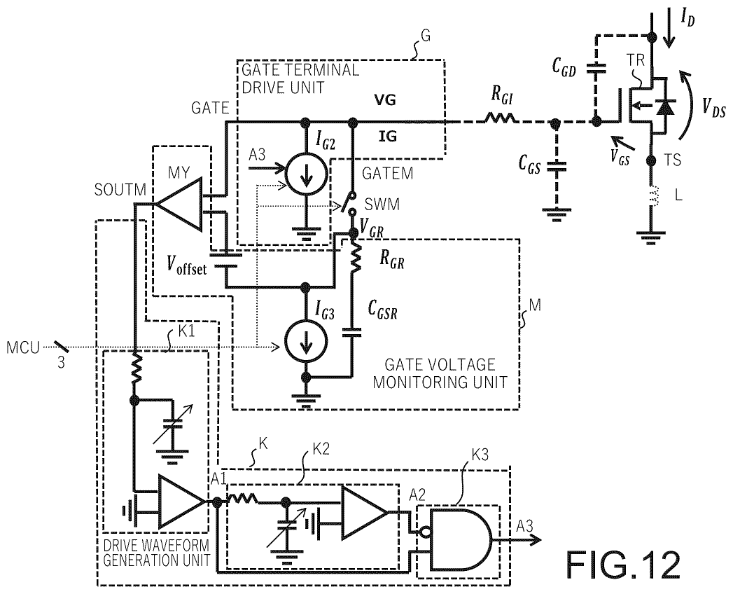

FIG. 8 is a diagram showing an example of the configuration of a drive system including an active gate control device according to the second embodiment. FIG. 9 is a diagram showing an example of a circuit configuration focusing on the gate terminal drive unit shown in FIG. 8. FIG. 10 is a diagram showing an example of a circuit configuration focusing on the gate voltage monitoring unit shown in FIG. 8. FIG. 11A is a diagram showing an example of a signal waveform for calibrating the monitoring current source and monitoring capacitor of the gate voltage monitoring unit shown in FIG. 8. FIG. 11B is a diagram showing an example of a signal waveform for calibrating the monitoring resistor of the gate voltage monitoring unit shown in FIG. 8. FIG. 12 is a diagram showing an example of a circuit configuration focusing on the gate voltage monitoring unit, drive waveform generation unit, and gate terminal drive unit of the active gate control device shown in FIG. 8.

It is noted that in the example of FIG. 8, the parasitic capacitance and parasitic resistance around the semiconductor switching device TR are omitted for clarity. Also, in the examples of FIG. 9 and FIG. 12, the dotted lines indicate the parasitic elements of the semiconductor switching device TR.

It is noted that in the following description of the active gate control device of the second embodiment, the description of components having the same symbols as those of the first embodiment may be omitted.

For example, as shown in FIG. 8, the drive system 2000 includes an active gate control device 200, a semiconductor switching device TR that is the driving target of the active gate control device 200, and a current source 10 that is connected between a power supply and one end (drain terminal) of the semiconductor switching device TR and outputs a current ID.

### Active Gate Control Device

The active gate control device 200 according to the second embodiment shown in FIG. 8 performs active gate control during turn-off of the semiconductor switching device TR.

In the example shown in FIG. 8, the active gate control device 200 according to the second embodiment has a circuit configuration that detects the timing of braking based on the monitoring signal SOUTM output by the gate voltage monitoring unit M.

This active gate control device 200, for example, as shown in FIG. 8, comprises a gate voltage monitoring unit M, a drive waveform generation unit K, a gate terminal drive unit G, a monitoring switch SWM, and a control unit MCU.

These configurations of the active gate control device 200 of this embodiment are described in detail below.

### Gate Terminal Drive Unit

In order to operate the semiconductor switching device TR, the gate terminal drive unit G controls the gate voltage VG of the gate terminal of the semiconductor switching device TR by controlling the drive current IG supplied to the gate terminal of the semiconductor switching device TR based on the gate control signal PWM output by the control unit MCU and the active gate control signal A3 output by the drive waveform generation unit K, as in the first embodiment.

The gate terminal drive unit G controls the operation of the semiconductor switching device TR in response to, for example, the gate control signal PWM, and the gate terminal drive unit G performs active gate control in response to the active gate control signal A3, and controls the voltage of the gate terminal of the semiconductor switching device TR so as to brake the turn-off operation of the semiconductor switching device TR.

This enables active gate control that reduces the gate drive strength applied to the gate terminal of the semiconductor switching device TR to an appropriate level at the appropriate timing.

In this embodiment, as shown in FIG. 9, the gate terminal drive unit G includes a current source IG2 that outputs a drive current IG in response to the gate control signal PWM output by the control unit MCU and the active gate control signal A3 output by the drive waveform generation unit K.

It is noted that the circuit configuration of the gate terminal drive unit G shown in FIG. 9 is just one example, and it may alternatively be implemented using any other configuration of performing the same function as the gate terminal drive unit G.

### Gate Voltage Monitoring Unit

The gate voltage monitoring unit M monitors the gate voltage VG of the gate terminal of the semiconductor switching device TR, and outputs a monitoring signal SOUTM based on the gate voltage VG.

As shown in FIG. 10, the gate voltage monitoring unit M includes, for example, a monitoring resistor RGR, a monitoring capacitor CGSR, a monitoring current source IG3, and a monitoring comparator MY.

The monitoring resistor RGR has one end connected to monitoring terminal TM.

The monitoring capacitor CGSR has one end connected to the other end of the monitoring resistor RGR, and the other end connected to ground.

The monitoring current source IG3, which is a variable current source, is connected between one end of the monitoring resistor RGR and the other end of the monitoring capacitor CGSR, and is controlled by the control unit MCU. This monitoring current source IG3 is used to discharge the charge stored in the monitoring capacitor CGSR in accordance with the turn-off operation.

The monitoring comparator MY compares the signal GATE, which is equal to the gate voltage VG of the gate terminal drive unit G, with the voltage obtained by adding an offset voltage Voffset to the monitoring voltage VGR at the monitoring terminal TM, which simulates the gate voltage VG using the monitoring resistor RGR and the monitoring capacitor CGSR, and outputs a monitoring signal SOUTM according to the comparison result.

For example, VGR+Voffset becomes less than or equal to the gate voltage VG, the monitoring comparator MY changes the monitoring signal SOUTM from a low level to a high level.

It is noted that the circuit configuration of the gate voltage monitoring unit M shown in FIG. 10 is just one example, and it may be configured with other circuit configurations that can perform similar functions.

### Drive Waveform Generation Unit

In this embodiment, the drive waveform generation unit K generates a gate drive waveform corresponding to the brake of active gate control based on the monitoring signal SOUTM output by the gate voltage monitoring unit M, and outputs an active gate control signal A3 for executing active gate control based on the gate drive waveform to the gate terminal drive unit G.

Thus, in this embodiment, the drive waveform generation unit K receives the monitoring signal SOUTM output by the gate voltage monitoring unit M instead of the detection signal SOUTD output by the DESAT circuit unit D, and outputs an active gate control signal A3 based on this monitoring signal SOUTM.

The drive waveform generation unit K then determines the time when the first delay time DX1 has elapsed from the starting point as the braking start timing, and determines the period from the braking start timing to the second delay time DX2 as the brake width for active gate control, thereby generating a gate drive waveform.

Then, the drive waveform generation unit K outputs an active gate control signal A3 for executing active gate control to the gate terminal drive unit G based on the gate drive waveform.

As shown in FIG. 12, the drive waveform generation unit K of this embodiment includes, for example, a first delay circuit K1, a second delay circuit K2, and a subtraction circuit K3. The drive waveform generation unit K outputs the third signal A3 to the gate terminal drive unit G as an active gate control signal A3 based on the third signal A3.

Thus, the drive waveform generation unit K has the same configuration as the first embodiment, except that the monitoring signal SOUTM output by the gate voltage monitoring unit M is input instead of the detection signal SOUTD output by the DESAT circuit unit D.

Here, as shown in FIG. 11A, the value of the variable current source IG3 or the monitoring capacitor CGSR is calibrated so that the monitoring voltage VGR closely matches the gate voltage VG.

For example, in the initial state, both the gate voltage VG and the monitoring voltage VGR are set to ground potential. The control unit MCU simultaneously supplies current from the current source IG2 and the monitoring current source IG3, charging the parasitic gate-source capacitance CGS and the monitoring capacitor CGSR for the same period.

Then, the control unit MCU adjusts the monitoring capacitor CGSR or monitoring current source IG3 so that the charged gate voltage VG and the monitoring voltage VGR become equal. In FIG. 11A, the steps observed at the start and end of current flow are due to the voltage drop that occurs in the parasitic resistance RGI or monitoring resistor RGR.

Next, as shown in FIG. 11B, the monitoring resistor RGR is calibrated. As in FIG. 11A, both the gate voltage VG and the monitoring voltage VGR are set to ground potential in the initial state.

When the control unit MCU starts to flow currents IG2 and IG3 at the same time, the voltage rises sharply by the amount of the voltage drop that occurs in the parasitic resistance RGI or monitoring resistor RGR. For example, a comparator (not shown) is used to determine whether the voltages are higher or lower, and the monitoring resistor RGR is adjusted repeatedly until the voltages become the same. The current flow is stopped once the comparator has determined whether the current is higher or lower, and the next adjustment is made.

### Monitoring Switch

The monitoring switch SWM is connected between the gate terminal drive unit G and the gate voltage monitoring unit M, for example, as shown in FIGS. 8 to 10 and 12, and is switched on or off under the control of the MCU.

### Control Unit

The control unit MCU controls the operation of the gate voltage monitoring unit M, and also controls the operation of the semiconductor switching device TR by the gate terminal drive unit G using a gate control signal PWM (Pulse Width Modulation signal).

### Operation of the Active Gate Control Device 200

Next, an example of the operation of the active gate control device 200 having the above configuration will be described.

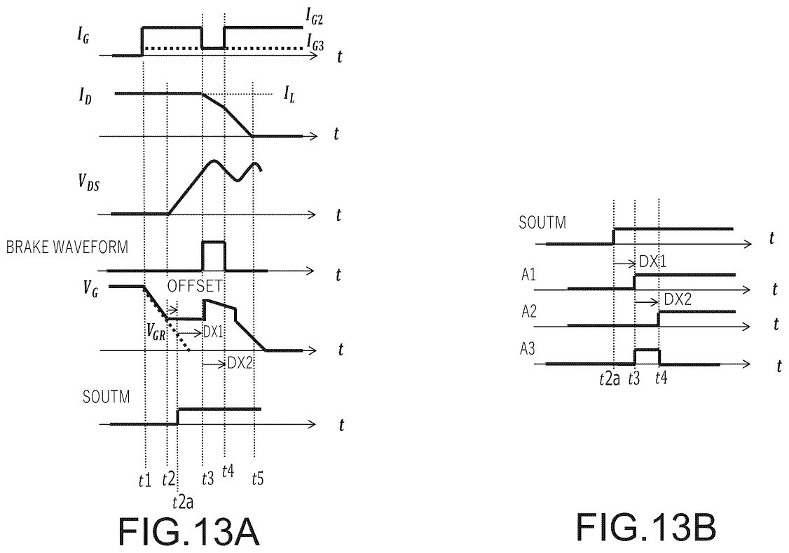

Here, FIG. 13A is a diagram showing an example of each signal and a brake waveform during a turn-off operation of the semiconductor switching device according to the second embodiment. FIG. 13B is a diagram showing an example of the waveform of each signal during a turn-off operation of the semiconductor switching device of the active gate control device according to the second embodiment. Note that in FIG. 13A, the drive current IG is written with the polarity in which the gate voltage of the semiconductor switching device TR drops as positive.

For example, when the semiconductor switching device TR is turned on, the control unit MCU turns on the monitoring switch SWM to connect the gate terminal of the semiconductor switching device TR to the monitoring terminal TM, and stops driving the monitoring current source IG3.

Immediately before and during the turning off of the semiconductor switching device TR, the control unit MCU turns off the monitoring switch SWM to disconnect the gate terminal from the monitoring terminal TM, and drives the monitoring current source IG3 to output a current.

Then, the gate voltage monitoring unit M outputs the monitoring signal SOUTM according to the comparison result when the semiconductor switching device TR is turned off, as follows.

For example, as shown in FIG. 13A, when the turn-off operation of the semiconductor switching device TR starts (time t1), both the gate voltage VG and the monitoring voltage VGR simulating the gate voltage VG decrease.

Then, the gate voltage VG decreases due to the parasitic capacitance CGD that forms the feedback path of the semiconductor switching device TR, and then enters the Miller plateau region where it remains nearly constant (after time t2). Meanwhile, the monitoring voltage VGR continues to decrease as shown by the dotted line (after time t2) because it has no feedback path.

Then, as shown in FIG. 13B, when the difference between the gate voltage VG and the monitoring voltage VGR exceeds the offset voltage Voffset of the monitoring comparator MY of the gate voltage monitoring unit M, the monitoring signal SOUTM rises to a high level (time t2a).

The time when this monitoring signal SOUTM rises to a high level is defined as the starting point (time t2a), and after the first delay time DX1 (time t3), braking of the drive current IG of the active gate control begins.

The drive waveform generation unit K outputs the first signal A1 (after time t3) by delaying the rising edge of the monitoring signal SOUTM by the first delay time DX1 in the first delay circuit K1 so that the rising edge of the monitoring signal SOUTM becomes the brake start point of the desired gate drive waveform.

Furthermore, the drive waveform generation unit K outputs the second signal A2 by delaying the first signal A1 by the second delay time DX2 in the second delay circuit K2 so that the rising edge of the monitoring signal SOUTM becomes the braking end point of the desired gate drive waveform (after time t4).

Then, the drive waveform generation unit K takes the difference between the first signal A1 and the second signal A2, and outputs the active gate control signal A3, whose waveform corresponds to the brake waveform.

It is noted that the braking timing varies depending on various conditions such as the characteristics of the semiconductor switching device, the junction temperature, the applied current, and the voltage, so the first delay time DX1 and the second delay time DX2 are set based on separate evaluation data.

As described above, the active gate control device 200 according to the second embodiment can execute active gate control and appropriately suppress ringing. In particular, for example, compared with the prior-art braking techniques described above, the effectiveness of active gate control can be enhanced by relatively shortening the brake width and reducing the brake level.

### Third Embodiment

Here, in the first and second embodiments described above, an example of the configuration of the active gate control device has been explained. However, the configuration of this active gate control device is not limited to this. Therefore, in this third embodiment, yet another example of the configuration of the active gate control device is explained.

In particular, in the second embodiment, the desired brake waveform was produced by introducing the first and second delay times, DX1 and DX2, relative to the monitoring signal SOUTM, but in this third embodiment, a circuit configuration in which only the first delay time DX1 is introduced.

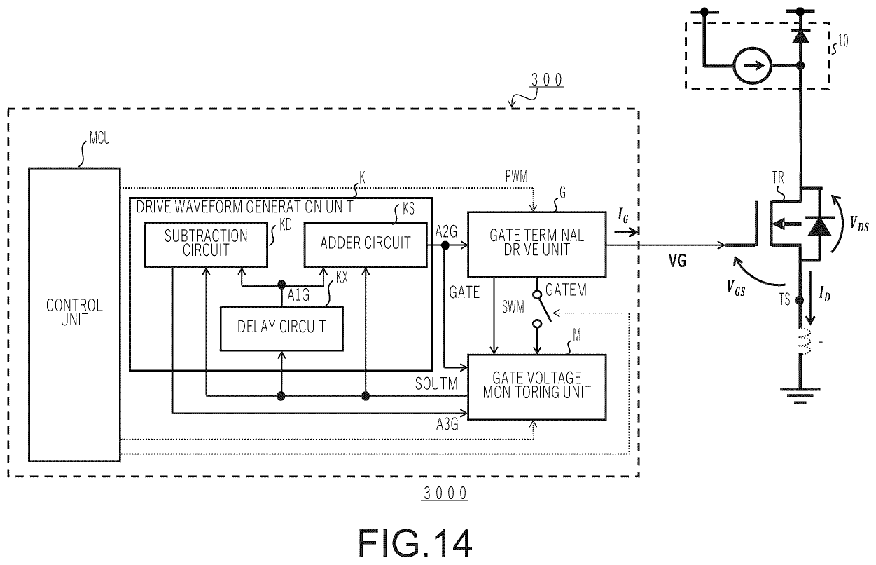

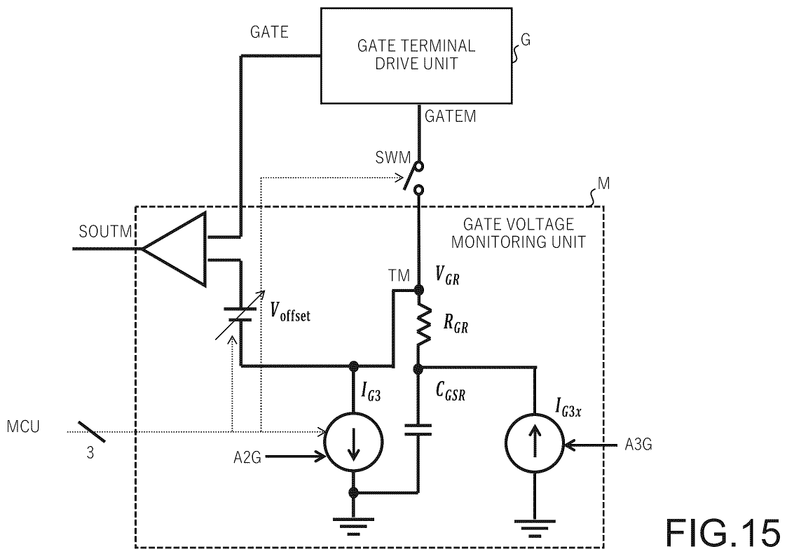

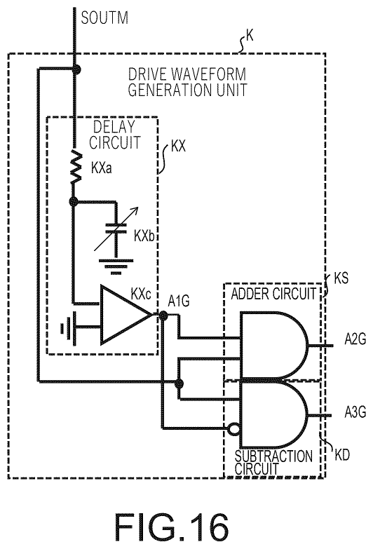

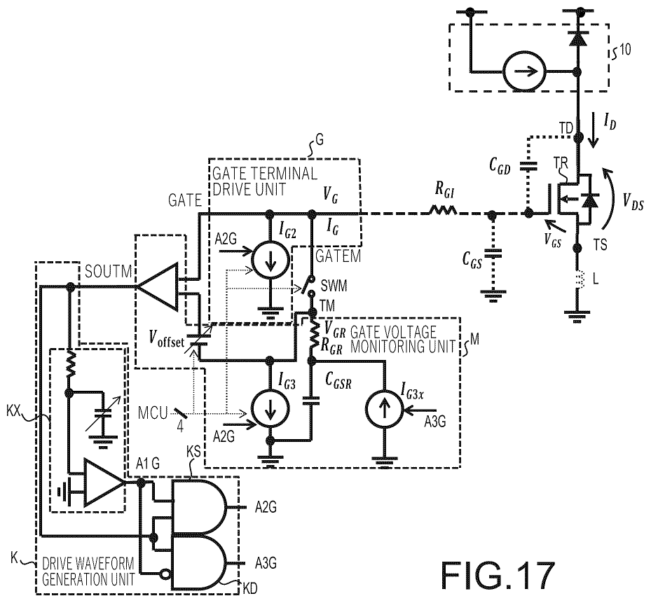

FIG. 14 is a diagram showing an example of the configuration of a drive system including an active gate control device according to the third embodiment. FIG. 15 is a diagram showing an example of a circuit configuration focusing on the gate voltage monitoring unit shown in FIG. 14. FIG. 16 is a diagram showing an example of a circuit configuration focusing on the drive waveform generation unit shown in FIG. 14. FIG. 17 is a diagram showing an example of a circuit configuration focusing on the gate voltage monitoring unit, drive waveform generation unit, and gate terminal drive unit of the active gate control device shown in FIG. 14.

Note that in the example of FIG. 14, the parasitic capacitances and parasitic resistances around the semiconductor switching device TR are omitted for clarity. In addition, in the example of FIG. 17, the dotted lines indicate the parasitic elements of the semiconductor switching device TR.

It is noted that in the following description of the active gate control device of the third embodiment, the description of the components having the same reference numerals as those of the first and second embodiments are omitted.

For example, as shown in FIG. 14, the drive system 3000 includes an active gate control device 300, a semiconductor switching device TR that is driven by the active gate control device 300, and a current source 10 that is connected between a power supply and one end (drain terminal) of the semiconductor switching device TR and outputs a current ID.

### Active Gate Control Device

The active gate control device 300 according to the third embodiment shown in FIG. 14 is configured to perform active gate control during turn-off of the semiconductor switching device TR.

In the example shown in FIG. 14, the active gate control device 300 according to the third embodiment has a circuit configuration that detects the timing of braking based on the monitoring signal SOUTM output by the gate voltage monitoring unit M.

This active gate control device 300, for example, as shown in FIG. 14, comprises a gate voltage monitoring unit M, a drive waveform generation unit K, a gate terminal drive unit G, a monitoring switch SWM, and a control unit MCU.

These configurations of the active gate control device 300 of this embodiment are described in detail below.

### Gate Terminal Drive Unit

As shown in FIG. 17, the gate terminal drive unit G controls the gate voltage VG of the gate terminal of the semiconductor switching device TR by controlling the drive current IG supplied to the gate terminal of the semiconductor switching device TR based on the gate control signal PWM output by the control unit MCU and the active gate control signal A2G output by the drive waveform generation unit K in order to operate the semiconductor switching device TR.

The gate terminal drive unit G controls the operation of the semiconductor switching device TR in response to, for example, the gate control signal PWM, and the gate terminal drive unit G controls the voltage of the gate terminal of the semiconductor switching device TR by active gate control in response to the active gate control signal A2G, so as to brake the turn-off operation of the semiconductor switching device TR.

This enables active gate control that reduces the gate drive strength applied to the gate terminal of the semiconductor switching device TR to an appropriate level at the appropriate timing.

In this embodiment, as shown in FIG. 17, the gate terminal drive unit G includes a current source IG2 that outputs a drive current IG in response to the gate control signal PWM output by the control unit MCU and the active gate control signal A2G output by the drive waveform generation unit K.

It is noted that the circuit configuration of the gate terminal drive unit G shown in FIG. 17 is just one example, and it may alternatively be implemented using any other configuration capable of performing the same function as the gate terminal drive unit G.

### Gate Voltage Monitoring Unit

The gate voltage monitoring unit M monitors the gate voltage VG at the gate terminal of the semiconductor switching device TR, and outputs a monitoring signal SOUTM based on the gate voltage VG.

As shown in FIG. 15, this gate voltage monitoring unit M includes, for example, a monitoring resistor RGR, a monitoring capacitor CGSR, a monitoring current source IG3, an additional monitoring current source IG3x, and a monitoring comparator MY.

One end of the monitoring resistor RGR is connected to a monitoring terminal TM.

The monitoring capacitor CGSR has one end connected to the other end of the monitoring resistor RGR and the other end connected to ground.

The monitoring current source IG3, which is a variable current source, is connected between one end of the monitoring resistor RGR and the other end of the monitoring capacitor CGSR, and is controlled by the control unit MCU. This monitoring current source IG3 is used to discharge the charge stored in the monitoring capacitor CGSR during turn-off.

The additional monitoring current source IG3x, which is a variable current source, is connected between one end of the monitoring resistor RGR and the other end of the monitoring capacitor CGSR. It is designed to pass a current of equal magnitude and opposite polarity to that of the monitoring current source IG3, and is configured to be activated after the Miller plateau so that the charge in the monitoring capacitor CGSR is not discharged and the monitoring voltage VGR can be held constant.

The monitoring comparator MY compares the signal GATE, which is equal to the gate voltage VG of the gate terminal drive unit G, with the voltage obtained by adding an offset voltage Voffset to the monitoring voltage VGR at the monitoring terminal TM, which simulates the gate voltage VG using the monitoring resistor RGR and the monitoring capacitor CGSR, and outputs a monitoring signal SOUTM according to the comparison result.

The method for calibrating the circuit element values of the gate voltage monitoring unit M is the same as in the second embodiment.

It is noted that the circuit configuration of the gate voltage monitoring unit M shown in FIG. 15 is an example, and other circuit configurations capable of performing similar functions may alternatively be used.

### Drive Waveform Generation Unit

In this embodiment, the drive waveform generation unit K generates a gate drive waveform corresponding to the active gate control brake based on the monitoring signal SOUTM output by the gate voltage monitoring unit M, and outputs an active gate control signal A2G to the gate terminal drive unit G for executing active gate control based on the gate drive waveform.

In this embodiment, the drive waveform generation unit K receives the monitoring signal SOUTM output by the gate voltage monitoring unit M instead of the detection signal SOUTD output by the DESAT circuit unit D, and outputs the active gate control signal A2G based on this monitoring signal SOUTM. In addition, in the third embodiment, the number of delay circuits is reduced from two to one compared with the first embodiment, and a combination of an adder(coincidence) circuit and a subtractor circuit is introduced.

As shown in FIG. 16, this drive waveform generation unit K includes, for example, a delay circuit KX, an adder circuit KS, and a subtractor circuit KD.

The delay circuit KX receives the monitoring signal SOUTM output by the gate voltage monitoring unit M and outputs a first signal A1G that is the monitoring signal SOUTM delayed by a delay time DX.

This delay circuit KX includes a resistor KXa, a variable capacitor KXb, and a comparator KXc, and outputs a first signal A1G that is the monitoring signal SOUTM delayed by a delay time DX using an RC network.

The adder circuit KS, implemented as an AND gate (coincidence detector), computes the logical product of the monitoring signal SOUTM and the first signal A1G, and outputs a second signal A2G, which specifies the interval in which SOUTM and A1G are both high, to the gate terminal drive unit G and the gate voltage monitoring unit M.

The subtraction circuit KD, implemented as an AND gate with inversion, outputs a third signal A3G, which specifies the interval in which SOUTM is high and A1G is low, to the gate voltage monitoring unit M.

In this way, the drive waveform generation unit K outputs the second signal A2G to the gate terminal drive unit G (as the active gate control signal) and to the gate voltage monitoring unit M, and outputs the third signal A3G to the gate voltage monitoring unit M.

It is noted that the circuit configuration of the drive waveform generation unit K shown in FIG. 16 is just an example, and the drive waveform generation unit K may alternatively be implemented using any other configuration capable of performing the same function.

### Monitoring Switch

The monitoring switch SWM is connected between the gate terminal drive unit G and the gate voltage monitoring unit M, for example, as shown in FIGS. 14, 15, and 17, and is switched on or off under control of the control unit MCU.

### Control Unit

The control unit MCU controls the operation of the gate voltage monitoring unit M, and also controls the operation of the semiconductor switching device TR by the gate terminal drive unit G using a gate control signal PWM (Pulse Width Modulation signal).

### Operation of Active Gate Control Device

Next, an example of the operation of the active gate control device 300 having the above configuration will be described.

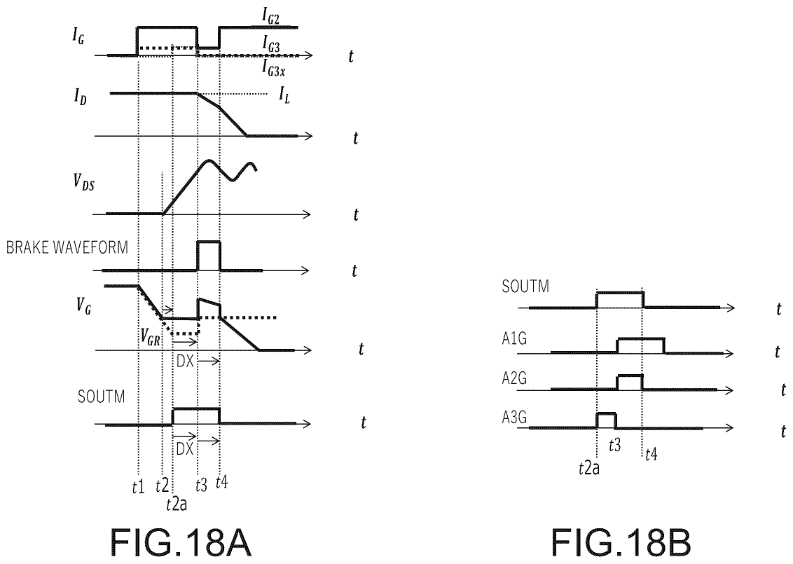

Here, FIG. 18A is a diagram showing an example of each signal and a brake waveform during a turn-off operation of the semiconductor switching device according to the third embodiment. FIG. 18B is a diagram showing an example of the waveform of each signal during a turn-off operation of the semiconductor switching device of the active gate control device according to the third embodiment. Note that in FIG. 18A, the drive current IG is written with the polarity in which the gate voltage of the semiconductor switching device TR drops as positive.

For example, when the semiconductor switching device TR is turned on, the control unit MCU turns on the monitoring switch SWM to connect the gate terminal of the semiconductor switching device TR to the monitoring terminal TM, and stops driving the monitoring current source IG3.

Immediately before and during turning off of the semiconductor switching device TR, the control unit MCU turns off the monitoring switch SWM to disconnect the gate terminal from the monitoring terminal TM, and drives the monitoring current source IG3 to output a current that discharges the monitoring capacitor CGSR.

Then, when the semiconductor switching device TR is turned off, the gate voltage monitoring unit M reduces the current of the monitoring current source IG3 in response to the second signal A2G, causes the additional monitoring current source IG3x to output a current to charge the monitoring capacitor CGSR in response to the third signal A3G, and outputs the monitoring signal SOUTM in response to the comparison result, as follows.

For example, as shown in FIG. 18A, when the turn-off operation of the semiconductor switching device TR starts (time t1), both the gate voltage VG and the voltage VGR simulating the gate voltage VG decrease (time t1 to t2).

At this time, when the difference between the gate voltage VG and the monitoring voltage VGR exceeds the offset voltage Voffset of the monitoring comparator MY of the gate voltage monitoring unit M, the monitoring signal SOUTM rises to a high level (time t2a).

Then, the subtraction circuit KD outputs the difference obtained by subtracting the first signal A1G from the monitoring signal SOUTM, and the output waveform of the third signal A3G also rises. As a result, the additional monitoring current source IG3x, which supplies a current of equal magnitude and opposite polarity to IG3, turns on. Consequently, the monitoring capacitor CGSR stops discharging and the monitoring voltage VGR, which simulates the gate voltage VG, remains constant (time t2a). This state continues for the delay time DX (time t2a to t3).

Next, when the braking start timing occurs, the drive strength of the current source IG2 driving the gate terminal is reduced, and the current of the monitoring current source IG3 of the gate terminal monitoring unit M becomes zero.

Then, the gate voltage VG briefly increases at the braking start timing and subsequently decreases slowly because it is driven with reduced strength.

On the other hand, since the current of the monitoring current source IG3 is zero, the monitoring voltage VGR briefly increases and then remains constant without further decreases. As a result, the gate voltage VG and the monitoring voltage VGR gradually approach each other.

During this period, the offset voltage Voffset of the monitoring comparator MY is adjusted, and when the difference between VG and VGR becomes smaller than Voffset, the monitoring signal SOUTM falls to a low level (time t4).

The braking timing of the active gate control is detected by setting the point where the monitoring signal SOUTM rises to a high level as the starting point (time t2a) and the point where it falls to a low level as the end point (time t4).

That is, the first signal A1G is output after being delayed by a delay time DX in the delay circuit KX so that the rising edge of the monitoring signal SOUTM corresponds with the braking start point (time t3) of the desired gate drive waveform.

After adjusting the offset voltage Voffset of the monitoring comparator MY to be smaller value than its initial settings, the time when the gate voltage VG becomes less than or equal to the monitoring voltage VGR plus the offset voltage Voffset is defined as the braking end point (time t4) of the gate drive waveform.

By outputting the waveform of the portion of the first signal A1G that coincides with the monitoring signal SOUTM, a signal waveform corresponding to the brake waveform is output as the second signal A2G.

It is noted that the braking timing varies depending on various conditions such as the characteristics of the semiconductor switching device, the junction temperature, the applied current, and the voltage, so the delay time DX and the offset voltage Voffset of the monitoring comparator MY are set based on separate evaluation data.

As described above, according to the active gate control device 300 of the third embodiment, active gate control can be executed to appropriately suppress ringing. In particular, for example, compared with the prior-art braking techniques described above, the effectiveness of active gate control can be enhanced by relatively shortening the brake width and reducing the brake level.

### Fourth Embodiment

Here, in the foregoing first to third embodiments, example configurations of an active gate control device were described. However, the configuration of this active gate control device is not limited thereto. Therefore, in this fourth embodiment, an example configuration of an active gate control device that combines the configurations of the first to third embodiments is described.

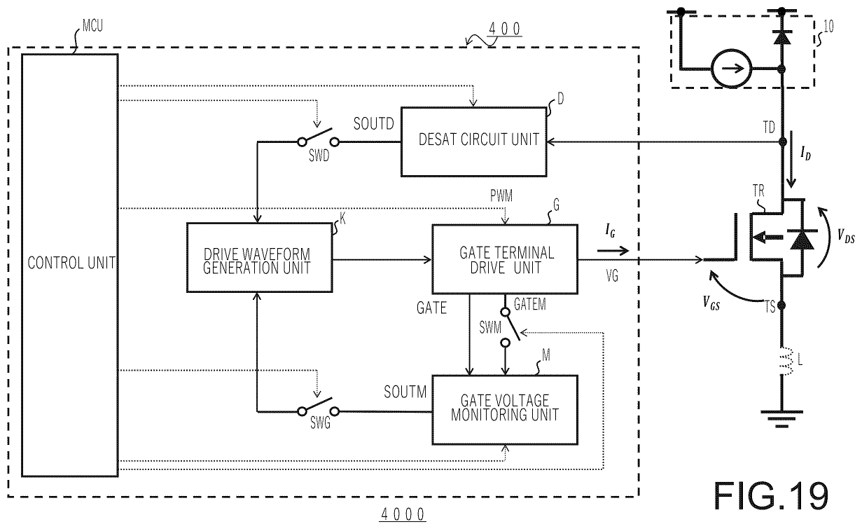

FIG. 19 shows an example of the configuration of a drive system including an active gate control device according to the fourth embodiment (block diagram of a circuit for detecting braking timing from both the DESAT terminal and the gate terminal). It is noted that in the following description of the active gate control device according to the fourth embodiment, the description of the components that are given the same reference numerals as those in the first to third embodiments are omitted.

As shown in FIG. 19, the drive system 4000 includes an active gate control device 400, a semiconductor switching device TR that is driven by the active gate control device 400, and a current source 10 that is connected between a power supply and one end (drain terminal) of the semiconductor switching device TR and outputs a current ID.

### Active Gate Control Device

The active gate control device 400 according to the fourth embodiment shown in FIG. 19 is configured to perform active gate control when the semiconductor switching device TR is turned on or off.

In the example shown in FIG. 19, the active gate control device 400 according to the fourth embodiment has a circuit configuration that detects braking timing based on both the detection signal SOUTD output by the DESAT circuit unit D and the monitoring signal SOUTM output by the gate voltage monitoring unit M.

This active gate control device 400, for example, as shown in FIG. 19, comprises a DESAT circuit unit D, a gate voltage monitoring unit M, a drive waveform generation unit K, a gate terminal drive unit G, a monitoring switch SWM, a first switch SWD, a second switch SWG, and a control unit MCU.

For example, when the semiconductor switching device TR is turned on, the drive waveform generation unit K generates a gate drive waveform corresponding to the brake of the active gate control based on the detection signal SOUTD output by the DESAT circuit unit D, and outputs an active gate control signal for executing active gate control based on the gate drive waveform to the gate terminal drive unit G.

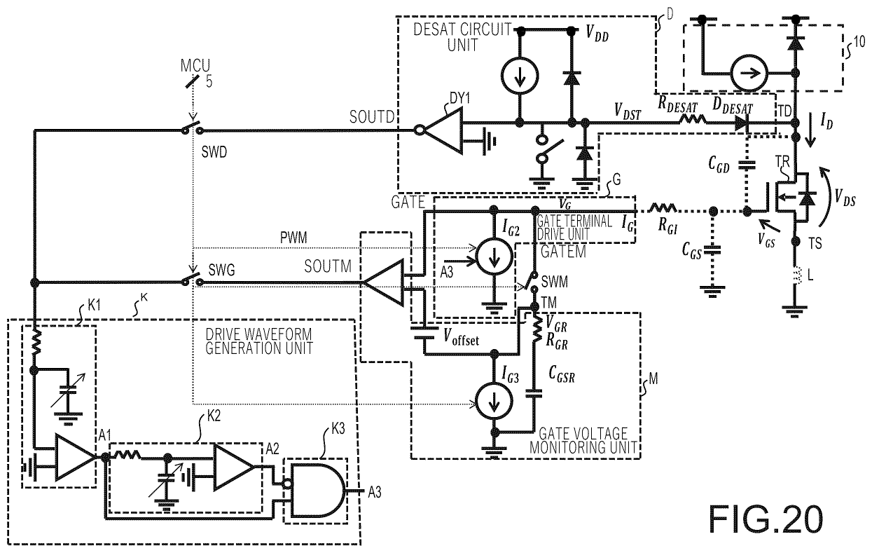

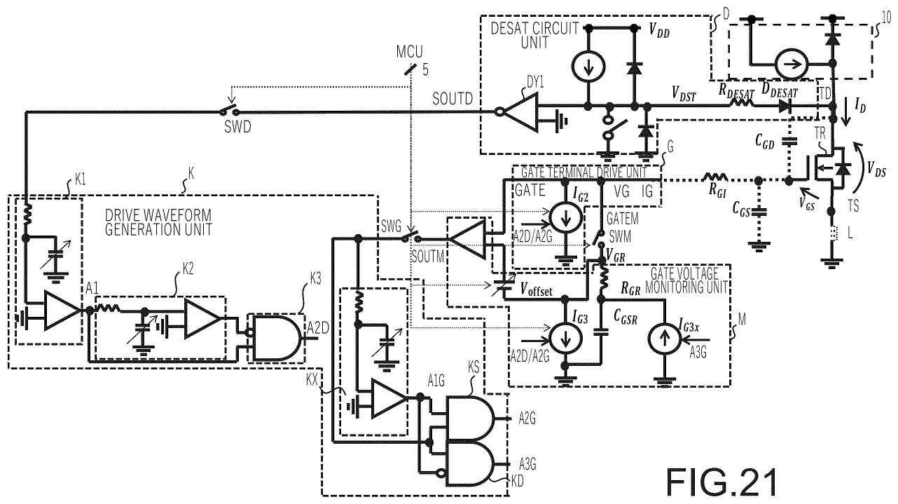

On the other hand, the drive waveform generation unit K generates a gate drive waveform corresponding to the brake of the active gate control based on the monitoring signal SOUTM output by the gate voltage monitoring unit M when the semiconductor switching device TR is turned off, and outputs an active gate control signal (e.g., A3 in the configuration of FIG. 20, or A2D in FIG. 21) for executing active gate control based on the gate drive waveform to the gate terminal drive unit G.

Here, when the semiconductor switching device TR is turned on, the control unit MCU turns on the first switch SWD and turns off the second switch SWG. On the other hand, when the semiconductor switching device TR is turned off, the control unit MCU turns off the first switch SWD and turns on the second switch SWG.

As a result, when the semiconductor switching device TR is turned on, the gate terminal drive unit G performs active gate control in response to the active gate control signal generated based on the detection signal SOUTD output by the DESAT circuit unit D, thereby controlling the voltage of the gate terminal of the semiconductor switching device so as to apply braking to the turn-on operation of the semiconductor switching device.

On the other hand, when the semiconductor switching device TR is turned off, the gate terminal drive unit G performs active gate control in response to the active gate control signal generated based on the monitoring signal SOUTM output by the gate voltage monitoring unit M, thereby controlling the voltage of the gate terminal of the semiconductor switching device so as to apply braking to the turn-off operation of the semiconductor switching device.

Here, in the example shown in FIG. 20, the configuration combines the first embodiment for turn-on and the second embodiment for turn-off. The detailed operation is as described in the respective embodiments.

Furthermore, in the example shown in FIG. 21, the configuration combines the first embodiment for turn-on and the third embodiment for turn-off. The detailed operation is as described in the respective embodiments.

In other words, according to the active gate control device 400 of the fourth embodiment, active gate control can be executed to appropriately suppress ringing. In particular, for example, compared with the prior-art braking techniques described above, the effectiveness of active gate control can be enhanced by relatively shortening the brake width and reducing the brake level.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An active gate control device that performs active gate control at a timing of turning on or off a semiconductor switching device, comprising:
a gate terminal drive unit that controls a gate voltage of the gate terminal of the semiconductor switching device by controlling a drive current supplied to the gate terminal of the semiconductor switching device in order to operate the semiconductor switching device;
a DESAT circuit unit that monitors a detection voltage based on a voltage between the drain and source of the semiconductor switching device, and outputs a detection signal based on the detection voltage;
a drive waveform generation unit that generates a gate drive waveform corresponding to a brake of active gate control based on the detection signal output by the DESAT circuit unit, and outputs an active gate control signal to the gate terminal drive unit for executing active gate control based on the gate drive waveform; and
a control unit that controls the operation of the DESAT circuit unit, and controls the operation of the semiconductor switching device by the gate terminal drive unit using a gate control signal.

2. The active gate control device according to claim 1,
wherein that the gate terminal drive unit controls the operation of the semiconductor switching device in response to the gate control signal, and the gate terminal drive unit performs active gate control in response to the active gate control signal to control the voltage of the gate terminal of the semiconductor switching device so as to brake a turn-on or turn-off operation of the semiconductor switching device.

3. The active gate control device according to claim 2,
wherein
the drive waveform generation unit detects a starting point for determining a brake start timing of the active gate control based on a change in a detection signal output by the DESAT circuit unit in response to a rise or fall of the drain-source voltage of the semiconductor switching device,
the drive waveform generation unit generates the gate drive waveform by determining a time when a first delay time has elapsed from the starting point as the brake start timing and a period from the brake start timing until a second delay time has elapsed as the brake width of the active gate control, and
the drive waveform generation unit outputs the active gate control signal for executing the active gate control to the gate terminal drive unit based on the gate drive waveform.

4. The active gate control device of claim 2,
wherein the drive waveform generation unit comprises:
a first delay circuit which receives the detection signal output by the DESAT circuit unit and outputs a first signal obtained by delaying the detection signal by the first delay time;
a second delay circuit which receives the first signal output by the first delay circuit and outputs a second signal obtained by delaying the first signal by a second delay time; and
a subtraction circuit which outputs a difference between the first signal output by the first delay circuit and the second signal output by the second delay circuit as a third signal for generating the gate drive waveform.

5. The active gate control device according to claim 4,
wherein the drive waveform generation unit outputs the active gate control signal to the gate terminal drive unit based on the third signal.

6. The active gate control device of claim 3,
wherein the drive waveform generation unit comprises:
a first delay circuit which receives the detection signal output by the DESAT circuit unit and outputs a first signal obtained by delaying the detection signal by the first delay time;
a second delay circuit which receives the first signal output by the first delay circuit and outputs a second signal obtained by delaying the first signal by a second delay time; and
a subtraction circuit which outputs a difference between the first signal output by the first delay circuit and the second signal output by the second delay circuit as a third signal for generating the gate drive waveform.

7. The active gate control device according to claim 6,
wherein the drive waveform generation unit outputs the active gate control signal to the gate terminal drive unit based on the third signal.

8. An active gate control device that performs active gate control at the timing of turning off a semiconductor switching device, comprising:
a gate terminal drive unit that controls a gate voltage of the gate terminal of the semiconductor switching device by controlling a drive current supplied to the gate terminal of the semiconductor switching device in order to operate the semiconductor switching device;
a gate voltage monitoring unit that monitors the gate voltage of the gate terminal and outputs a monitoring signal based on the gate voltage;
a drive waveform generation unit that generates a gate drive waveform corresponding to braking of active gate control based on the monitoring signal output by the gate voltage monitoring unit and outputs an active gate control signal to the gate terminal drive unit for executing active gate control based on the gate drive waveform; and
a control unit that controls the operation of the gate voltage monitoring unit and controls the operation of the semiconductor switching device by the gate terminal drive unit using a gate control signal.

9. The active gate control device according to claim 8,
wherein that the gate terminal drive unit controls the operation of the semiconductor switching device in response to the gate control signal, and the gate terminal drive unit performs active gate control in response to the active gate control signal to control the voltage of the gate terminal of the semiconductor switching device so as to brake a turn-off operation of the semiconductor switching device.

10. The active gate control device according to claim 8,
wherein the drive waveform generation unit comprises:
a first delay circuit that receives the monitoring signal output by the gate voltage monitoring unit and outputs a first signal obtained by delaying the monitoring signal by the first delay time;
a second delay circuit that receives the first signal output by the first delay circuit and outputs a second signal obtained by delaying the first signal by a second delay time; and
a subtraction circuit that outputs a difference between the first signal output by the first delay circuit and the second signal output by the second delay circuit as a third signal for generating the gate drive waveform, and
wherein the drive waveform generation unit outputs an active gate control signal to the gate terminal drive unit based on the third signal.

11. The active gate control device according to claim 9,
wherein the drive waveform generation unit comprises:
a first delay circuit that receives the monitoring signal output by the gate voltage monitoring unit and outputs a first signal obtained by delaying the monitoring signal by the first delay time;
a second delay circuit that receives the first signal output by the first delay circuit and outputs a second signal obtained by delaying the first signal by a second delay time; and
a subtraction circuit that outputs a difference between the first signal output by the first delay circuit and the second signal output by the second delay circuit as a third signal for generating the gate drive waveform, and
wherein the drive waveform generation unit outputs an active gate control signal to the gate terminal drive unit based on the third signal.

12. The active gate control device according to claim 8, further comprising a monitoring switch connected between the gate terminal drive unit and the gate voltage monitoring unit and controlled to be turned on or off by the control unit,
wherein the gate voltage monitoring unit comprising:
a monitoring resistor that has one end connected to the monitoring terminal;
a monitoring capacitor that has one end connected to the other end of the monitoring resistor and the other end connected to ground;
a monitoring current source that is connected between one end of the monitoring resistor and the other end of the monitoring capacitor and controlled by the control unit; and
a monitoring comparator that compares the gate voltage of the gate terminal drive unit with a voltage obtained by adding an offset voltage to the monitoring voltage of the monitoring terminal and outputs the monitoring signal according to a comparison result.

13. The active gate control device according to claim 9, further comprising a monitoring switch connected between the gate terminal drive unit and the gate voltage monitoring unit and controlled to be turned on or off by the control unit,
wherein the gate voltage monitoring unit comprising:
a monitoring resistor that has one end connected to the monitoring terminal;
a monitoring capacitor that has one end connected to the other end of the monitoring resistor and the other end connected to ground;
a monitoring current source that is connected between one end of the monitoring resistor and the other end of the monitoring capacitor and controlled by the control unit; and
a monitoring comparator that compares the gate voltage of the gate terminal drive unit with a voltage obtained by adding an offset voltage to the monitoring voltage of the monitoring terminal and outputs the monitoring signal according to a comparison result.

14. The active gate control device according to claim 8, further comprising a monitoring switch connected between the gate terminal drive unit and the gate voltage monitoring unit and controlled to be turned on or off by the control unit.

15. The active gate control device according to claim 14,
wherein the drive waveform generation unit includes:
a delay circuit that receives the monitoring signal output by the gate voltage monitoring unit, and outputs a first signal obtained by delaying the monitoring signal by a delay time;
an adder circuit that calculates the logical product of the monitoring signal and the first signal, and outputs a second signal that defines the timing at which the monitoring signal and the first signal match to the gate terminal drive unit and the gate voltage monitoring unit; and
a subtractor circuit that outputs a third signal that defines the difference between the monitoring signal and the first signal to the gate voltage monitoring unit.

16. The active gate control device according to claim 15,
wherein the gate voltage monitoring unit comprises:
a monitoring resistor that has one end connected to a monitoring terminal;
a monitoring capacitor that has one end connected to the other end of the monitoring resistor and the other end connected to ground;
a monitoring current source that is connected between one end of the monitoring resistor and the other end of the monitoring capacitor, and is controlled by the control unit;
a monitoring comparator that compares the gate voltage of the gate terminal drive unit with a voltage obtained by adding an offset voltage to the monitoring voltage of the monitoring terminal and outputs the monitoring signal according to a comparison result; and
an additional monitoring current source that is connected between one end of the monitoring resistor and the other end of the monitoring capacitor.

17. The active gate control device according to claim 9, further comprising a monitoring switch connected between the gate terminal drive unit and the gate voltage monitoring unit and controlled to be turned on or off by the control unit.

18. The active gate control device according to claim 17,
wherein the drive waveform generation unit includes:
a delay circuit that receives the monitoring signal output by the gate voltage monitoring unit, and outputs a first signal obtained by delaying the monitoring signal by a delay time;
an adder circuit that calculates the logical product of the monitoring signal and the first signal, and outputs a second signal that defines the timing at which the monitoring signal and the first signal match to the gate terminal drive unit and the gate voltage monitoring unit; and
a subtractor circuit that outputs a third signal that defines the difference between the monitoring signal and the first signal to the gate voltage monitoring unit.

19. The active gate control device according to claim 18,
wherein the gate voltage monitoring unit comprises:
a monitoring resistor that has one end connected to a monitoring terminal;
a monitoring capacitor that has one end connected to the other end of the monitoring resistor and the other end connected to ground;
a monitoring current source that is connected between one end of the monitoring resistor and the other end of the monitoring capacitor, and is controlled by the control unit;
a monitoring comparator that compares the gate voltage of the gate terminal drive unit with a voltage obtained by adding an offset voltage to the monitoring voltage of the monitoring terminal and outputs the monitoring signal according to a comparison result; and
an additional monitoring current source that is connected between one end of the monitoring resistor and the other end of the monitoring capacitor.

20. An active gate control device that performs active gate control at the timing of turning on or off a semiconductor switching device, the active gate control device comprising:
a gate terminal drive unit that controls a gate voltage of the gate terminal of the semiconductor switching device by controlling a drive current supplied to the gate terminal of the semiconductor switching device in order to operate the semiconductor switching device;
a DESAT circuit unit that monitors a detection voltage based on a voltage between the drain and source of the semiconductor switching device and outputs a detection signal based on the detection voltage;
a gate voltage monitoring unit that monitors the gate voltage of the gate terminal and outputs a monitoring signal based on the gate voltage;
a drive waveform generation unit that generates a gate drive waveform corresponding to the brake of active gate control based on the detection signal output by the DESAT circuit unit when the semiconductor switching device is turned on, and outputs an active gate control signal to the gate terminal drive unit for executing active gate control based on the gate drive waveform, on the other hand, the drive waveform generation unit generates the gate drive waveform based on the monitoring signal output by the gate voltage monitoring unit when the semiconductor switching device is turned off, and outputs an active gate control signal to the gate terminal drive unit for executing active gate control based on the gate drive waveform; and
a control unit that controls the operation of the semiconductor switching device by the gate terminal drive unit using a gate control signal,
wherein the gate terminal drive unit controls the operation of the semiconductor switching device according to the gate control signal, and the gate terminal drive unit controls the voltage of the gate terminal of the semiconductor switching device by performing active gate control according to the active gate control signal, to brake the turn-on or turn-off operation of the semiconductor switching device.
